(19) United States
(12) Patent Application Publication
(10) Pub. No.: US 2017/0088952 A1
(43) Pub. Date: Mar. 30, 2017

(54) High-throughput multichamber atomic layer deposition systems and methods

(71) Applicant: Ultratech, Inc., San Jose, CA (US)

(72) Inventor: Andrew M. Hawryluk, Los Altos, CA (US)

(73) Assignee: Ultratech, Inc., San Jose, CA (US)

(21) Appl. No.: 15/270,019

(22) Filed: Sep. 20, 2016

Related U.S. Application Data
(60) Provisional application No. 62/233,575, filed on Sep. 28, 2015.

(51) Int. Cl. C23C 16/455; C23C 16/458; C23C 16/52; C23C 16/44

(52) U.S. Cl. CPC C23C 16/45551; C23C 16/4408; C23C 16/45536; C23C 16/4584; C23C 16/52

(57) ABSTRACT

ALD systems and methods having high throughput are disclosed. The ALD systems and methods employ a process chamber that has multiple chamber sections defined by interior chamber dividers. The wafers to be processed are supported on a platen that rotates beneath a process chamber housing with a small gap therebetween so that the wafers are moved between the chamber sections. The multiple chamber sections are pneumatically partitioned by the dividers and by pneumatic valves operably disposed therein and in pneumatic communication with the platen surface through the gap. Some chamber sections are used to perform an ALD process using process gasses, while other chamber sections are transition sections that include a purge gas. Some chamber sections can be employed to perform a laser process or a plasma process on the wafers passing therethrough.

### FIELD

The present disclosure relates to atomic layer deposition, and in particular relates to atomic layer deposition systems and methods having high throughput.

The entire disclosure of any publication or patent document mentioned herein is incorporated by reference, including U.S. Pat. Nos. 5,997,963; 6,066,210; 7,833351; 8,877,300; and U.S. Patent Application Publications No. US 2010/00183825 and US 2013/0196078.

### BACKGROUND

Atomic layer deposition (ALD) is a method of depositing a thin film on a substrate in a very controlled manner. The deposition process is controlled by using two or more chemicals in vapor form (i.e., “process gasses”) and reacting them sequentially and in a self-limiting manner on the surface of the substrate such as a silicon wafer. The sequential process is repeated to build up the thin film layer by layer, wherein the layers are atomic scale.

ALD is used to form a wide variety of films, such as binary, ternary and quaternary oxides for advanced gate and capacitor dielectrics, as well as metal-based compounds for interconnect barriers and capacitor electrodes.

The ALD process can be carried out in a single chamber system, as is well known in the art. However, the ALD process is relatively slow as compared to for example chemical vapor deposition and like processes. The typical ALD process introduces a first process gas into the single process chamber. The sample sits in this environment for a short period of time to expose the surface to the first process gas. Typically, less than 1 sec is required for this step, and it has been shown that only a few milliseconds are actually required.

Once the surface is saturated with the first process gas, the first process gas is pumped out of the chamber. Then an inert or purge gas is flowed through the chamber. Then a second process gas is introduced into the chamber. The second process gas reacts with the surface of the substrate that was saturated by the first process gas. The purpose of the inert gas flowing through the chamber before the second process gas is flowed into the chamber is to ensure that all of the original unreacted process gas is removed. The second process gas reacts with the surface of the substrate that was saturated with the first process gas. Once this second reaction process is completed (in a few milliseconds), the second process gas is removed and the chamber is again purged with an inert gas. Then, the first process gas is introduced into the chamber and the entire reaction sequence is repeated until an ALD film of a desired thickness is obtained.

The basic reason why an ALD process is slow is not related to the reaction rate of the process gasses at the substrate surface. This reaction is relatively quick. The ALD process takes a long time because of the time required to flow process gas into the chamber, pump out the process gas, flow inert gas, pump out the inert gas, then flow the next process gas into the chamber, etc. It is the flow mechanics that limit the throughput of the ALD and not the reaction rates. Each deposition sequence usually takes several seconds, and an entire cycle can take minutes.

Furthermore, the primary reason why the ALD process is expensive is that each ALD layer that makes up the ALD film consumes relatively large quantities of expensive process gasses. Typically, the reaction chamber is much larger than the substrate. With each cycle, the process gas is pumped out. The actual utilization of the process gases in the ALD reactions is typically a small fraction of 1%.

To speed up the ALD process, multiple ALD chambers can be used. Alternatively, a large chamber that contains multiple substrates can be used to perform what is known as batch processing. Either way, speeding up the ALD process to increase the throughput of substrates translates into reduced cost per substrate. In addition, simplification of the ALD systems can also be used to reduced costs. In particular, reducing the cost of ownership of the ALD system (and in particular, a multichamber ALD system) can be used to reduce the cost per substrate.

Consequently, there is a need for improved ALD systems and methods that increase throughput while avoiding complexity that adds to the system costs and to the production costs.

### SUMMARY

The present disclosure is directed to ALD systems and methods that simplify the ALD process while also reducing the cost of the ALD process by reducing the amounts of process gasses used. Aspects of the ALD systems and methods include containing the process gases within separate process sections of a process chamber and moving the substrate between the separate chamber sections without having to remove the gases from the chamber sections.

An aspect of the disclosure is a process chamber for a multichamber ALD system for performing ALD on multiple wafers. The process chamber includes: a housing having an interior divided into multiple chamber sections by chamber dividers disposed within the housing interior, the housing having an open bottom end; a rotatable platen having a central axis and an upper surface that supports the multiple wafers and that is operably disposed with its upper surface adjacent the bottom end of the housing and spaced apart therefrom by a gap, wherein the platen is rotatable to move the wafers between the multiple chamber sections; and a pneumatic valve operably disposed in each chamber divider, wherein each pneumatic valve is in pneumatic communication with the platen surface within the gap and forms a pneumatic partition between adjacent chamber sections.

Another aspect of the disclosure is a multichamber ALD system that includes the the process chamber disclosed herein and as described above; a process gas system operably connected to at least two of the chamber sections; and a purge gas system operably connected to at least two of the chamber sections different than the two chamber sections operably connected to the process gas system.

Another aspect of the disclosure is a method of performing ALD on multiple wafers each having a surface to form an ALD film on each of the wafers. The method includes: supporting the multiple wafers on a surface of a platen that is spaced apart from a process chamber housing by a gap G that is 500 microns or less, wherein the process chamber includes multiple chamber sections; pneumatically partitioning the process chamber sections; rotating the platen beneath the process chamber housing, thereby causing the wafers to move between the chamber sections; and performing an ALD process in at least one of the chambers sections as the wafers pass through the chamber sections to form the ALD film.

Other aspects of the method include performing at least one of laser processing and plasma processing of the wafers in one or more of the chamber sections. The rotation rate of the platen is limited only by the reaction rates of the particular process gasses with the wafer surface or the ALD film layer formed on the wafer surface during each full platen rotation.

Additional features and advantages are set forth in the Detailed Description that follows, and in part will be readily apparent to those skilled in the art from the description or recognized by practicing the embodiments as described in the written description and claims hereof, as well as the appended drawings. It is to be understood that both the foregoing general description and the following Detailed Description are merely exemplary, and are intended to provide an overview or framework to understand the nature and character of the claims.

### BRIEF DESCRIPTION OF THE DRAWINGS

The accompanying drawings are included to provide a further understanding, and are incorporated in and constitute a part of this specification. The drawings illustrate one or more embodiment(s), and together with the Detailed Description serve to explain principles and operation of the various embodiments. As such, the disclosure will become more fully understood from the following Detailed Description, taken in conjunction with the accompanying Figures, in which:

FIG. 1 is a schematic diagram of a high-throughput multichamber ALD system according to the disclosure;

FIG. 2 is a top-down cut-away view of an example process chamber that includes four dividers that define four chamber sections;

FIG. 3 is a top elevated view of an example platen showing four wafers operably supported thereon;

FIG. 4A is a top-elevated view of an example wafer that includes a surface on which is formed an ALD film using the system and methods disclosed herein;

FIG. 4B is a cross-sectional view of the wafer of FIG. 4A, further including an ALD film formed on the wafer surface, wherein the close-up inset shows the ALD film as formed from multiple ALD film layers;

FIGS. 5A through 5D are close-up cross-sectional views of the platen and the adjacent divider, illustrating the operation of the pneumatic valve within the divider to form a pneumatic partition between adjacent chamber sections;

FIG. 6A is similar to FIG. 5A and illustrates an example P-V-P pneumatic configuration for the pneumatic valve disclosed herein;

FIG. 6B is similar to FIG. 5C and illustrates another example P-V-P pneumatic configuration for the pneumatic valve disclosed herein;

FIGS. 7A and 7B are similar to FIG. 2 and illustrated two different chamber embodiments that include five chamber sections (FIG. 7A) and six chamber sections (FIG. 7B).

FIG. 8 is similar to FIG. 1 and illustrates an example multichamber ALD system that includes a laser system operably arranged to perform laser processing (e.g., laser annealing, laser-enhanced LED, etc.) in at least one of the chamber sections;

FIG. 9 is a top elevated view of a wafer within a chamber section and showing a laser beam forming a line image at wafer surface, wherein the line image is scanned over the wafer surface by the movement of the wafer underneath to perform laser processing as part of the overall ALD process;

FIG. 10 is similar to FIG. 8 and illustrates an example multichamber ALD system that includes a plasma source system operably arranged to perform plasma processing (e.g., plasma-enhanced ALD) in at least one of the chamber sections; and

FIG. 11 is a close-up view of a wafer in the chamber section that has plasma processing capability and showing the plasma flowing from the plasma source system to the wafer surface.

### DETAILED DESCRIPTION

Reference is now made in detail to various embodiments of the disclosure, examples of which are illustrated in the accompanying drawings. Whenever possible, the same or like reference numbers and symbols are used throughout the drawings to refer to the same or like parts. The drawings are not necessarily to scale, and one skilled in the art will recognize where the drawings have been simplified to illustrate the key aspects of the disclosure.

The claims as set forth below are incorporated into and constitute part of this Detailed Description.

Cartesian coordinates are shown in some of the Figures for the sake of reference and are not intended to be limiting as to direction or orientation.

In the discussion below, a “process gas” may be constituted by one or more gas constituents or may consist of a single gas constituent. A process gas is one that is reactive with the surface of a substrate (wafer), including an ALD film layer that is formed on the wafer surface.

Also in the discussion below, a “purge gas” is a non-reactive gas such nitrogen or one or more other inert gasses that do not react in any substantial way with the wafer surface or an ALD film layer that is formed on the wafer surface.

The phrase “between P and Q” as used below where P and Q are numerical values includes the values P and Q.

In the discussion below, a full rotation of the platen is one where the platen rotation starts from an initial position and returns to the initial position, i.e., the platen rotates 360 degrees.

In the discussion below, two process gasses 111 and 112 are discussed by way of example. When referring generally to a “process gas,” the reference number 111 is used for convenience, and it will be understood that such reference can also apply to the other process gas 112 or additional process gases.

Multichamber ALD System

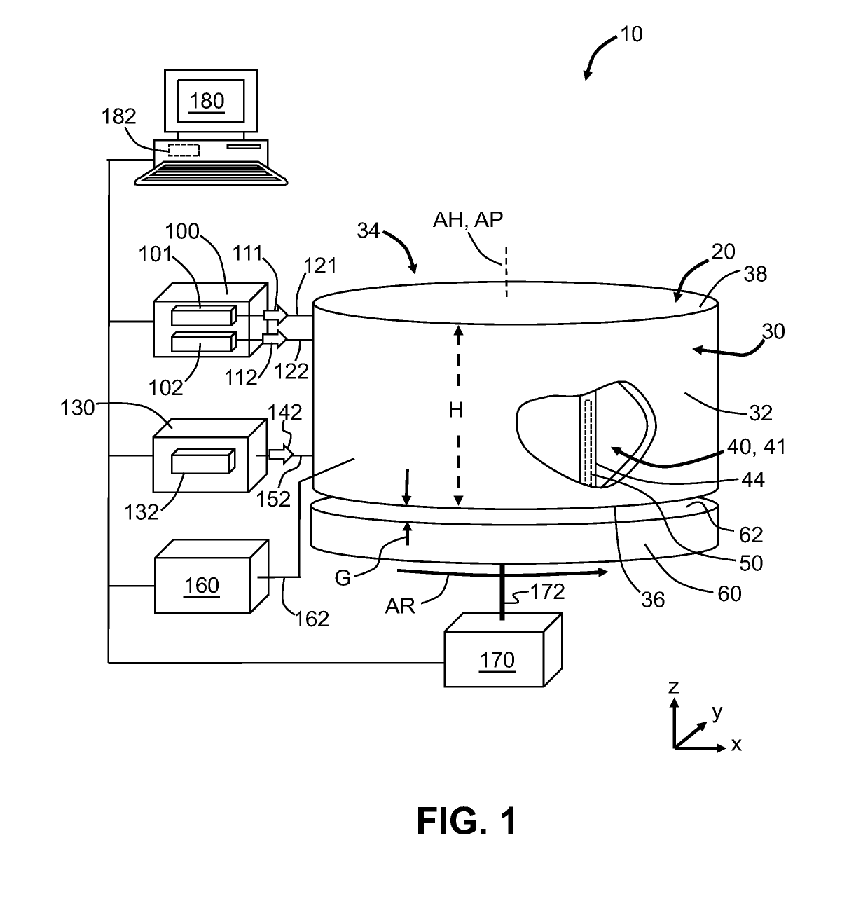

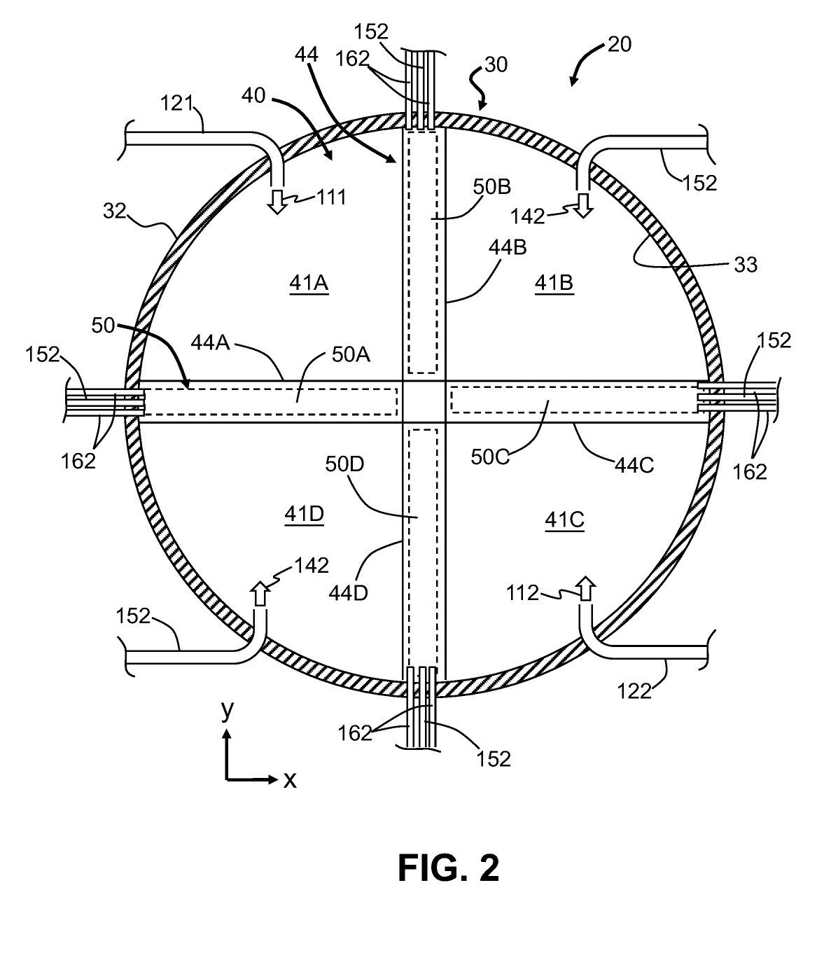

FIG. 1 is a schematic diagram of a high-throughput multichamber ALD system (“system”) 10. System 10 includes a process chamber 20, an example of which is shown in a top-down cut-away view in FIG. 2. The process chamber 20 includes a housing 30 that has a side wall 32 with an inner surface 33, a top end 34 and a bottom end 36. Housing 30 has a central housing axis AH. The top end 34 includes a top wall 38 while the bottom end is open. In an example, side wall 32 is cylindrical with a circular cross-sectional shape. In another example, housing 30 can have a side wall 33 of any reasonable cross-sectional shape, including having multiple facets, but preferably having its inner surface 33 defining a circular cross-sectional shape.

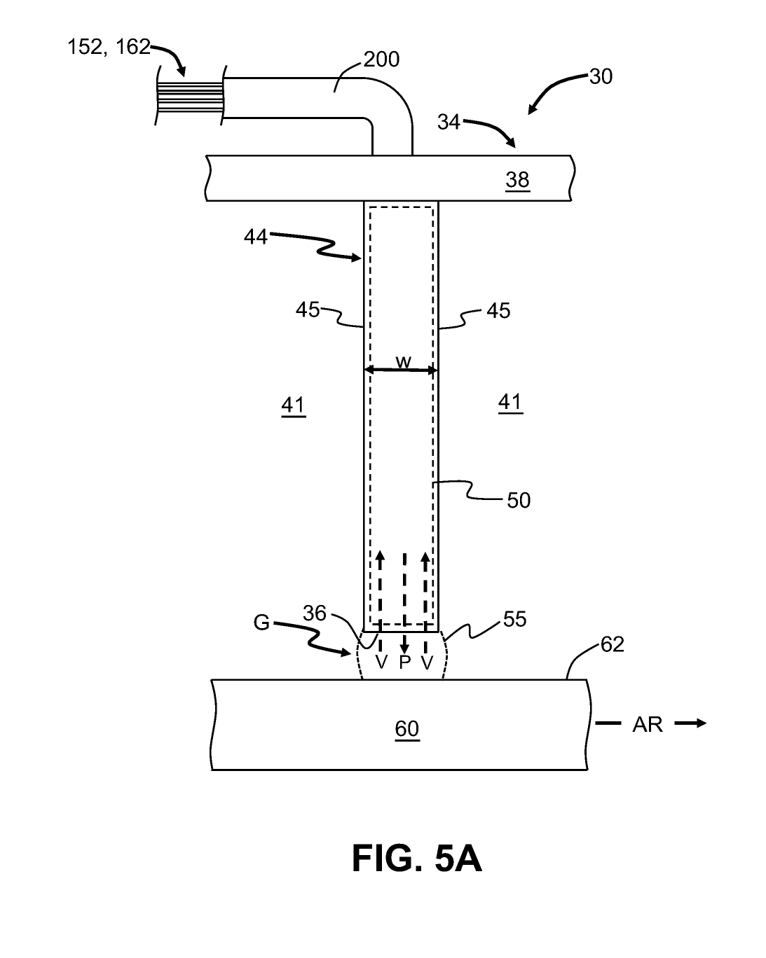

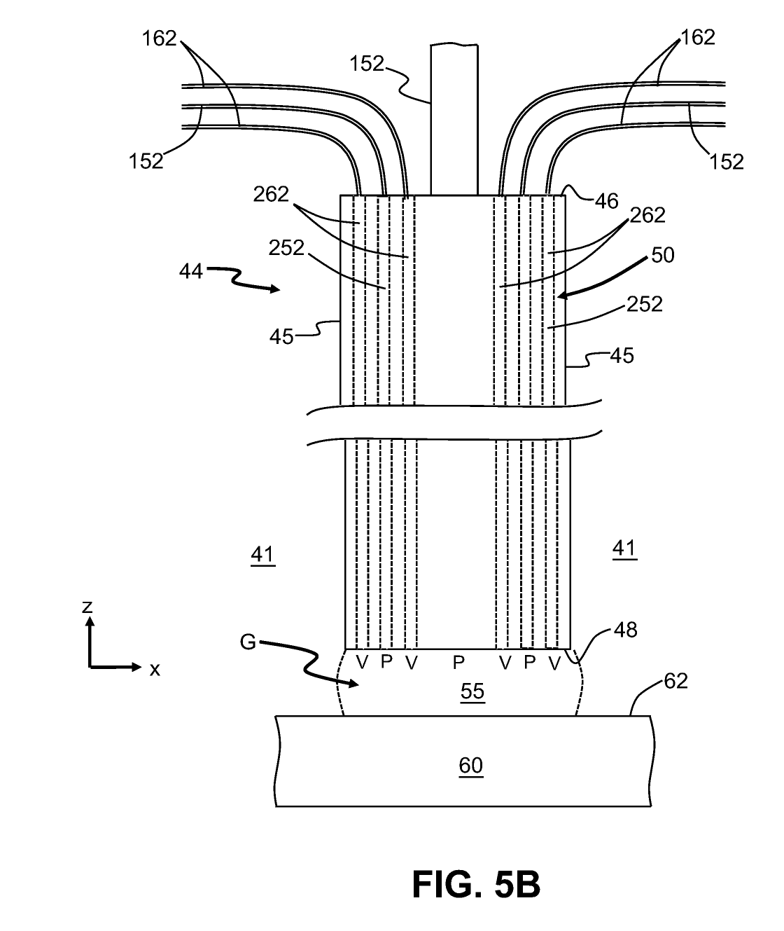

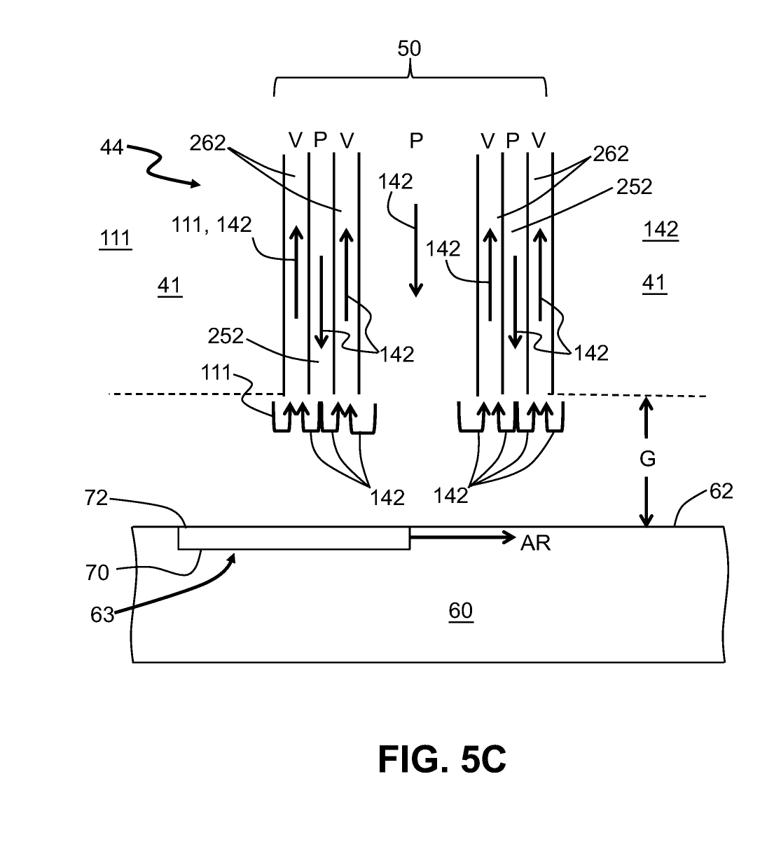

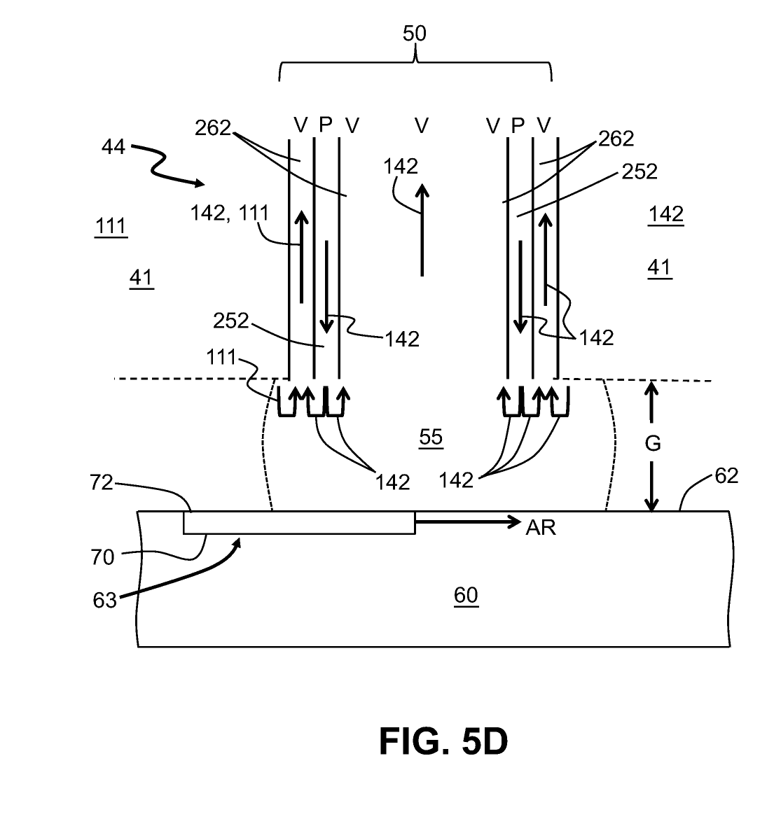

The housing 30 of process chamber 20 includes an interior 40 having a height (“interior height”) H as measured between top and bottom ends 34 and 36 of housing 30. The interior 40 includes dividers 44 that in an example radially extend from housing axis AH. FIG. 2 shows an example where housing 30 includes four dividers 44, individually denoted as 44A, 44B, 44C and 44D. Each divider 44 includes opposite sides 45, a top edge 46 and a bottom edge 48. The dividers 44 define within interior 40 multiple interior chamber sections 41. In an example, dividers 44 are arranged such that all of the chamber sections have substantially the same size, shape and volume. The four example dividers 44A through 44D that define four chamber sections 41A through 41D are shown in FIG. 2. Each divider 44 includes a pneumatic valve 50, as described in greater detail below. Each divider 44 has a width w, which in an example is in the range from 5 mm≦w≦25 mm (see FIG. 5A, introduced and discussed below). In an example, the opposite sides 45 of each divider 44 are planar.

As discussed below, system 10 is configured to process multiple wafers 70 having a thickness TH_{W} and a diameter or width W_{d}. In an example, the interior height H can be selected so that interior chamber sections 41 use relatively small amounts of process gas or purge gas when processing wafers 70. In an example, the interior height H is in the range 5·TH_{W}≦H≦100·TH_{W} or 10·TH_{W}≦H≦50·TH_{W} or 10·TH_{W}≦H≦20·TH_{W}. Thus, for an example wafer thickness TH_{W}=750 microns, an example interior height can be between about 1 cm and 5 cm.

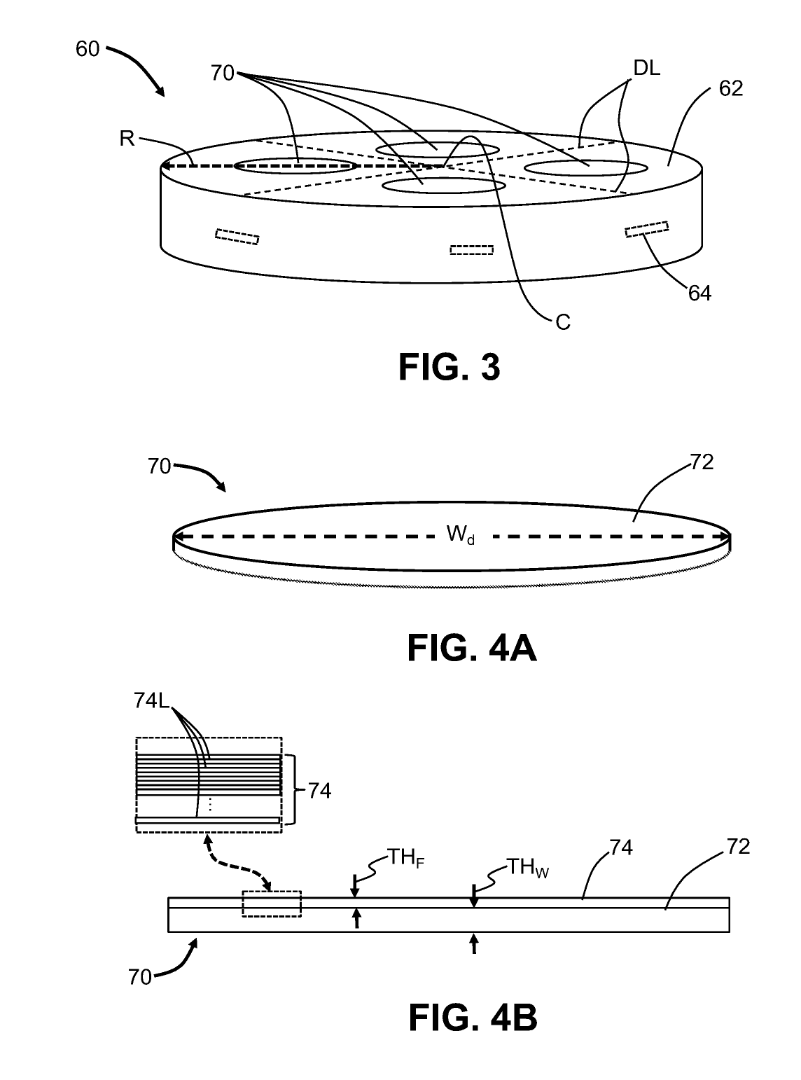

Process chamber 20 also includes a rotatable platen 60. FIG. 3 is a top-elevated view of an example platen 60. Platen 60 has an upper surface 62, a center C, a central axis AP that passes through center C, and a radius R. The platen upper surface 62 is configured to support a plurality of wafers 70 (e.g., 4 wafers, as shown) to be processed. The dashed lines DL in FIG. 3 show an example position of where the four dividers 44 can reside above upper surface 62 so that one wafer 70 resides in each chamber section 41. In an example, platen 60 constitutes an electrostatic chuck that serves to hold wafers 70 in place and keep them flat.

Platen 60 is arranged adjacent bottom end 36 of housing 30 and spaced apart therefrom in the z-direction to define a gap G. In an example, the gap G is in the range from 50 microns to 500 microns. In an example, gap G<1 mm. In an example, upper surface 62 of platen 60 includes recesses 63 each sized to accommodate a wafer 70 so that the wafer surface 72 resides at or below the upper surface of the platen (See FIG. 5C, introduced and discussed below). In an example, recess 63 are formed such that the wafer surface 72 is flush with platen upper surface 62. In an example, at least one of housing 30 and platen 60 is movable in the z-direction so that wafers 70 can be operably disposed on the platen upper surface 62, as well as to adjust the size of gap G.

FIG. 4A is a top-elevated view of an example wafer 70, which includes an upper surface (“surface”) 72 on which the ALD process is carried out, as described below. Each chamber section 41 is configured to accommodate at least one wafer 70, e.g., at least one 100 mm wafer, or at least one 200 mm wafer or at least one 300 mm wafer or at least one 450 mm wafer. In an example, each chamber section 41 can contain multiple wafers 70. In an example, if the centers of wafers 70 with a diameter W_{d}=200 mm are placed approximately 750 mm from the center C of platen 60, then a total of twenty 200 mm wafers can be supported on the platen surface 62. If the centers of the wafers are place approximately 425 mm from the center C of platen 60, then a total of ten 200 mm wafers can be supported on the platen surface 62.

The platen radius R needed to support n wafers of diameter W_{d} can be approximated by the equation:

R=(n)·(W_{d})/(2π)+(W_{d}/2)

FIG. 4B is a cross-sectional view of wafer 70 illustrating an example ALD film 74 formed on upper surface 72 using system 10 and the methods described herein. The close-up inset in FIG. 4B shows that the ALD film 74 is made up of a number of individual layers 74L formed during each ALD deposition process or cycle, as described below. The ALD film layers 74L may not actually be discrete but are shown as such to illustrate how the ALD film 74 is built up layer by layer in stages to a desired thickness TH_{F}.

In an example, platen 60 is configured to heat wafers 70 to up to 400° C. to facilitate the ALD process. This heating capability can be achieved, for example, by one or more heating elements 64 operably arranged either within or in thermal contact with platen 60, as shown in FIG. 3.

With reference again to FIG. 1, system 20 also includes a process gas system 100 that is operably connected to process chamber 20. In an example, process gas system 100 includes a first process gas supply 101 that contains a first process gas 111 and a second process gas supply 102 that contains a second process gas 112. Additional process gas supplies can also be used, depending on the particular ALD process being carried out, and two process gas supplies are shown by way of example. In the art of ALD, a process gas is also referred to as a “precursor” or a “precursor gas.”

With reference also to FIG. 2, in an example, first process gas supply 101 is operably connected to chamber section 41A via a first gas line 121 and second process gas supply 102 is operably connected to chamber section 41C via a second gas line 122. The process gas system 100 can also include additional process gases and additional gas lines to other chamber sections 41, such as employed in embodiments where laser annealing or other process is carried out as part of the ALD process, as discussed below.

System 20 also includes a purge gas system 130 that is operably connected to process chamber 20. The purge gas system 130 includes a purge gas supply 132 that contains a purge gas 142, such as nitrogen or another inert gas. In the example shown in FIG. 2, purge gas supply 132 is operably connected to chamber sections 41B and 41D via purge gas lines 152, as illustrated in FIG. 2. Purge gas supply 132 is also operably connected to pneumatic valves 50 in each divider 44 via additional purge gas lines 152.

System 10 also includes a vacuum system 160 operably connected to pneumatic valves 50 in dividers 44 via vacuum lines 162.

The chamber sections 41 can be kept at a substantially constant pressure, i.e., they need not have their particular gas pumped out and then added back again as is done in conventional ALD systems. Rather, the gas remains in the given chamber section 41 and the wafers are moved into the different chambers sections via the rotation of platen 60 beneath housing 30. This also creates a slight pressure differential with respect to the pneumatic valves 50 that reside between the chamber sections. In one example, this pressure differential is “negative” encourages the flow of gas into the gaps G under dividers 44 and into the pneumatic valves, which substantially prevents the flow of gas to the adjacent chamber section by creating gas curtain between chamber sections. In another example, the pressure differential is “positive” so that flow of purge gas from the pneumatic valves 50 discourages the flow of gas in the adjacent chamber sections 41 into the corresponding gap G under divider 44.

Because the process gases 101, 102, etc. remain in their respective chamber sections 41 rather than being pumped out between process steps, system 10 substantially reduces the cost of the ALD deposition process. As noted above, a large portion of the ALD process cost is associated with the process gas. In prior art systems, a chamber for a 200 mm wafer and that has a 10 mm chamber height occupies approximately 500 cm³ and the gas pressure is nominally 100 millitorr. For each ALD film layer, all the process gas is pumped out and replaced. For a 1000 layer pair, 2×500 cm³×1000×100 millitorr=10⁵ cm³-torr of expensive gas is consumed. In system 10 and the related methods disclosed herein, the volume of a chamber section 41 is filed once so that about 1000 times less process gas is consumed.

With reference again to FIG. 1, system 20 also includes a drive motor 170 operably connected to rotatable platen 60 via a mechanical drive device 172, such as a drive shaft, so that the platen rotates about its central axis AP, as indicated by arrow AR. In an example, the platen central axis is co-axial with the housing central axis AH, as shown in FIG. 1.

System 20 further includes a controller 180 operably connected to process gas system 100, purge gas system 130 and vacuum system 160 and drive motor 170. Controller 180 is generally configured to control the operation of system 10, e.g., by instructions embodiment in a non-transitory computer-readable medium 182 within or operably connected to the controller.

FIGS. 5A through 5D are four different close-up x-z cross-sectional views of platen 60 and the adjacent divider 44 that separates adjacent chamber sections 41, and showing the pneumatic valve 50 within divider 44. The pneumatic valves 50 can also be referred to as Bernoulli valves. The pneumatic valve 50 is operably connected to vacuum system 160 and purge gas system 130, e.g., via a conduit 200 that includes purge gas lines 152 and vacuum lines 162. pneumatic valve 50 includes at least one purge gas channel 252 operably connected to at least one purge gas line 152, and includes at least two vacuum channels 262 operably connected to at least two vacuum lines 162. The purge gas channels 252 and the vacuum channels 262 run generally in the z-direction from the top edge 46 to the bottom edge 48 of divider 44 and are open at the bottom edge.

Process chamber 20 is configured such that each chamber section 41 contains a particular gas, e.g., a particular process gas or a purge gas. The pneumatic valve 50 and the purge gas channels 252 and vacuum channels 262 therein are configured to pneumatically isolate adjacent chamber sections 41. Each pneumatic valve 50 is in pneumatic communication with the upper surface 62 of platen 60 through gap G and forms a pneumatic partition between adjacent chamber sections 51.

To accomplish this pneumatic partitioning, in one example each pneumatic valve 50 includes at least two vacuum channels 262 that respectively reside closest to the sides 45 of divider 44, and also includes at least one purge channel 252 that resides between the two vacuum channels (i.e., the two vacuum channels sandwich the at least one purge channel). This pneumatic configuration can be described from left to right as “V-P-V,” where “V” stands for vacuum and “P” stands for purge (see FIG. 5A). The “V” corresponds to the vacuum channels 262 while the P corresponds to the purge gas channel 252. There are a variety of different types of “V-P-V” pneumatic configurations where vacuum V's are on the “outside” while one or more pressure P's and one or more other vacuum V's reside between the outside vacuum V's.

While it is preferable that then pneumatic partitioning between adjacent chamber sections 41 be as robust as possible, it is noted here that it need not be perfect. In an example, some process gas from one chamber section 41 can migrate to the adjacent chamber section, and some purge gas can migrate from one chamber section to the adjacent chamber section, as long as the amount of migrating gas involved is insubstantial. Here, insubstantial means that it does not substantially alter the ALD process that occurs within the given chamber section 41, i.e., does not substantially affect the quality of the final ALD film 74 being formed. If relative few atoms of gas migrate from one chamber section to another as compared to the amount of gas that is already in the chamber section. the impact on the formation of the final ALD film will be insubstantial.

The example configuration of the pneumatic valve 50 shown in FIGS. 5B and 5C has a large central purge channel 252. Moving outward from this central purge channel 252 on either side is a V-P-V channel configuration. Thus, the channel configuration from the left side 45 of the divider 44 to the right side defines a pneumatic configuration that can be described as V-P-V-P-V-P-V. This pneumatic configuration notation is included in FIGS. 5B and 5C for ease of understanding.

FIG. 5D is similar to FIG. 5C and shows a V-P-V-P-V pneumatic configuration wherein the central purge gas channel 252 has been replaced by a central vacuum channel 262, and the two innermost vacuum channels 262 have been incorporated into the larger central vacuum channel.

The basic V-P-V pneumatic configuration for pneumatic valve 50 (i.e., purge gas sandwiched by vacuum) allows for the purge gas 142 to flow through central purge gas channel 252 into gap G and spread out laterally only to be picked up a short distance later within the gap on each side of the purge gas channel by the adjacent vacuum channels 262. In addition, the outside “V” channels 262 respectively collect gas from their adjacent chamber section 41. In particular, the left-most vacuum channel 262 collects first process gas 111 from left-side chamber section 41 and that flows into gap G, while the right-most vacuum channel 262 collects purge gas 142 that resides within the right-side chamber section 41 and that also flows into gap G.

Likewise, the V-P-V-P-V-P-V of FIGS. 5B and 5C and the V-P-V-P-V configuration of FIG. 5D operate in a similar manner while providing additional pneumatic isolation of (i.e., pneumatic partitioning between) adjacent chamber sections 41. In particular, with reference to the V-P-V-P-V-P-V configuration, the outermost vacuum channels 262 serve to respectively remove first process gas 111 from left-side chamber section 41 and purge gas 142 from right-side chamber section 41 as well removing purge gas 142 from the adjacent purge gas channels 262.

Meanwhile, the innermost vacuum channels 262 respectively remove purge gas 142 from center purge gas channel 252 and the other adjacent purge gas channel. The downward flow of purge gas 142 under pressure in purge gas channels 252 and the upward flow of purge gas and process gas 111 under vacuum in vacuum channels 262 results in dynamic circulation of gasses that creates a gas buffer or “gas curtain” 55 that prevents the migration of substantial amounts of process gas and purge gas between adjacent chamber sections 41.

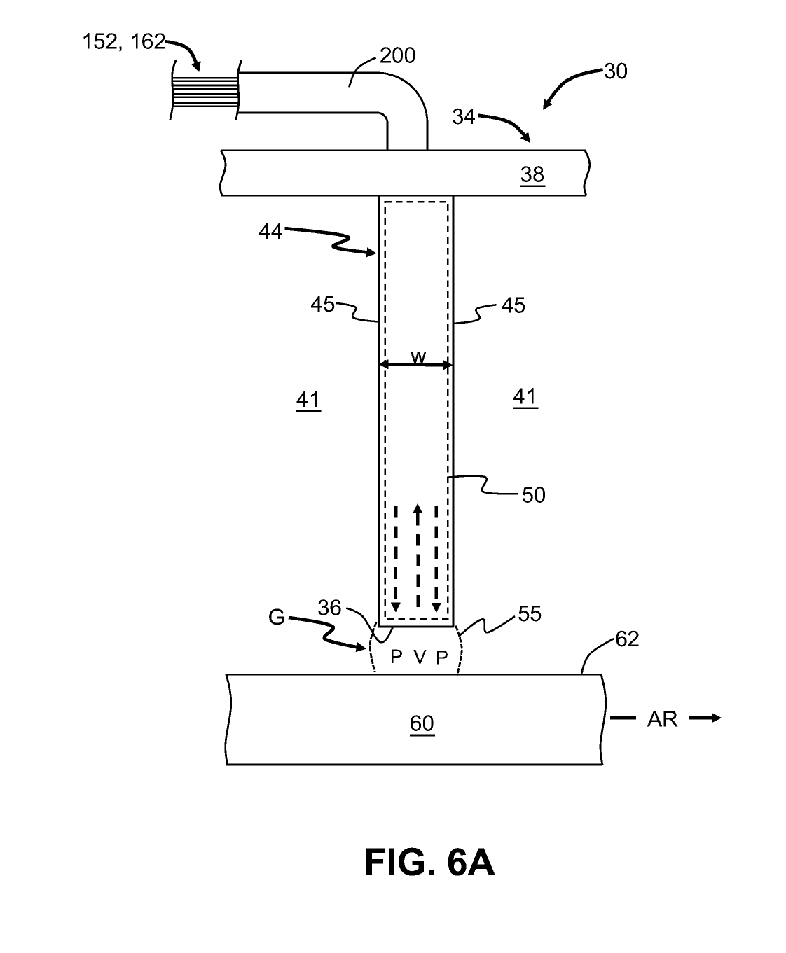

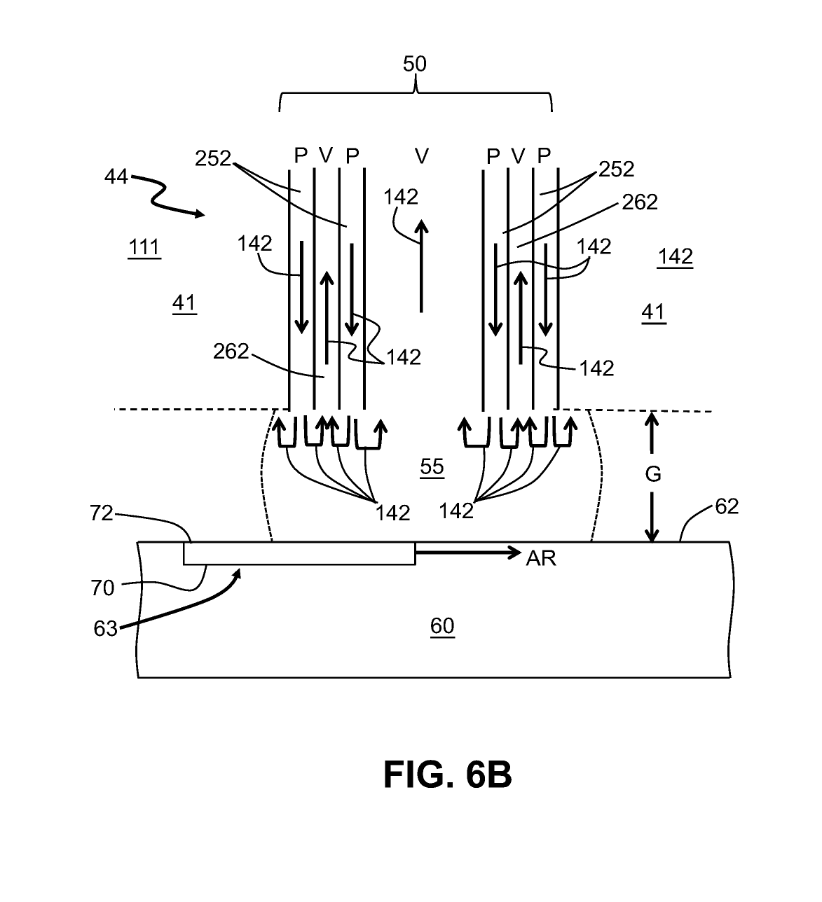

An alternate pneumatic configuration for pneumatic valve 50 is based on a P-V-P configuration, i.e., purge gas pressure P on the outside and vacuum V on the inside. FIG. 6A is similar to FIG. 5A and illustrates the P-V-P pneumatic configuration. Different P-V-P pneumatic configurations using purge channels 252 and vacuum channels 262 can be employed that are analogous to those in FIGS. 5B through 5D, such as P-V-P-V-P-V-P and P-V-P-V-P. FIG. 6B is similar to FIG. 5C and illustrates another example P-V-P pneumatic configuration for pneumatic valve 50. Thus, the P-V-P configuration calls for at least two purge channels 252 and at least one vacuum channel 262.

The general P-V-P configuration will typically allow some purge gas 142 to flow into the adjacent chamber sections 41. Here, the purge gas pressure P is substantially the same or slightly greater than the pressure in the adjacent chamber sections 41. In the case of one of the chamber sections 41 being a purge gas section, the migration of purge gas from pneumatic valve 50 into the purge gas chamber section is of no consequence. In the case where one of the chamber sections 41 contains a process gas, the amount of purge gas 142 that enters the process gas chamber section is insubstantial and thus has no substantial effect on the ALD process being carried out. On the other hand, the small amount of purge gas 142 that can migrate into the process gas chamber section 41 can serve to reduce or prevent the flow of process gas 111 into the pneumatic valve, i.e., can mitigate the loss of expensive process gas.

General Method of Operation

In the general operation of system 10, substrates 70 are disposed on the upper surface 62 of platen 60 and supported thereby, such as shown in FIG. 3. The substrates can be placed on the platen simultaneously and can reside in recesses 63 (see FIG. 5C). The drive motor 170 is then activated, which causes platen 60 to rotate about is central axis AP, which in an example is co-axial with housing central axis AH as shown in FIG. 1. This acts to move wafers 70 between adjacent chamber sections 41, e.g., from 41A→41B→41C→41D→41A, etc. Thus, a given wafer 70 will be cycled in order between chamber sections 41 for each full rotation of platen 60. In an example, platen 60 is rotated in a continuous manner, i.e., without stopping, including in one example rotating at a substantially constant rotation rate. In another example, platen can be rotated with one or more stops within a given complete or full rotation, or can be rotated using a variable rotation rate.

Since wafer surface 72 becomes saturated with process gas 111 in a matter of milliseconds, platen 60 can rotate fairly quickly. For example, if platen 60 rotates at 60 revolutions per minute (RPM) (i.e., 1 rotation per second), a wafer 70 will reside within each chamber section for a total of approximately 250 milliseconds (the “residence time”), which is sufficient to saturate the wafer surface 72. An example range on the rotation rate for platen 60 is between 10 RPM and 200 RPM or between 30 and 100 RPM.

In an example, the rotation rate of the platen 60 is such that the residence time of a wafer 70 in a given chamber section is between 100 milliseconds and 1000 milliseconds (i.e., 1 second), or between 200 milliseconds and 750 milliseconds, or between 250 milliseconds and 500 milliseconds. In an example, the residence time is measured from when the leading edge of the wafer 70 first enters the chamber section 41 until when the trailing edge of the wafer leaves the chamber section. It is noted that whatever non-uniform processing occurs by having a leading-edge portion of the wafer entering a given chamber section while the trailing edge remains outside of the chamber section is compensated by the non-uniform exposure to the trailing-edge portion of the wafer as the leading edge wafer leaves and resides outside of the given chamber section.

During the rotation of platen 60 and the attendant movement of wafers 70 between chamber sections 41, the pneumatic valves 50 in dividers 44 respectively serve as pneumatic partitions that pneumatically isolate adjacent chamber sections while allowing for a sufficient gap G for the wafers to move underneath housing 30 of chamber 20. As explained above, this pneumatic partitioning is accomplished by a combination of the flow of purge gas 142 under pressure via purge gas channels 252 and the judicious use of vacuum via vacuum channels 262 operably connected to vacuum system 160 via vacuum lines 162. As noted above, the pneumatic valve 50 creates gas curtain 55 that pneumatically isolates adjacent chamber sections 41.

The small amount of gas (process or purge) in a given chamber section 41 that is removed by the pneumatic valves 50 is replaced using the corresponding gas source to maintain the pressure in the chamber section. The amount of gas lost in this manner can be kept small by adjusting the vacuum levels and the flow of purge gas 142, and by keeping the gap G as small as possible. Also, as noted above, the consumption rate of process gas can be kept low or at a minimum by having a small or minimum size for gap G.

In an example, every other chamber sections 41 (e.g., 41A, 41C, . . . ) is a processing section while each intervening chamber section (e.g., 41B, 41D, . . . ) is a non-processing chamber section. In an example, processing chamber sections 41 contain gasses that are different than those in non-processing chamber sections. In an example, the primary purpose of non-processing chamber sections 41 are to separate the processing chamber sections and to provide transition locations where wafers 70 are prepared for the next process. In another embodiment, one or both of chamber sections 41B and 41D can also be configured as processing chamber sections.

An example ALD process that can be carried out in system 10 having four chamber sections 41 (41A through 41D) to form an AL₂O₃ film 74 is set forth in Table 1 below.

TABLE 1
Example four-chamber process for forming Al₂O₃ film

| Chamber | Gas |
|---|---|
| 41A | Tri-Methyl-Alumina (111) |
| 41B | Nitrogen Purge (142) |
| 42C | Water Vapor (H₂O) (112) |
| 42D | Nitrogen Purge (142) |

Another example ALD process that can be carried out in system 10 having four chamber sections 41 (41A through 41D) to form a GaN film is set forth in Table 2 below.

TABLE 2
Example four-chamber process for forming Al₂O₃ film

| Chamber | Gas |
|---|---|
| 41A | Tri-Methyl-Gallium (111) |
| 41B | Nitrogen Purge (142) |
| 42C | Tri-Methyl-Gallium (111) |
| 42D | Nitrogen Purge |

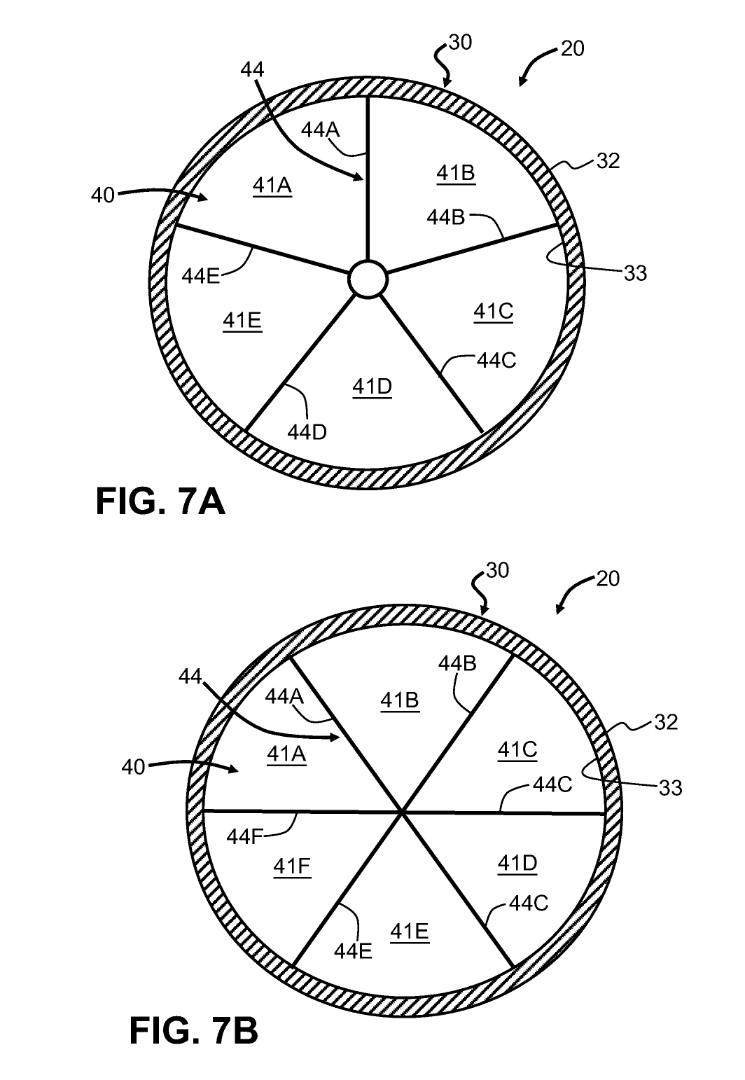

System 10 is not limited to a total of four chamber sections 41 as discussed in the examples above. FIG. 7A is similar to FIG. 2 and shows a top-down cut-away view of an example chamber 20 that includes five dividers 44, denoted 44A through 44E, that define five chamber sections 41, denoted 41A through 41E. In this example embodiment of chamber 20, chamber sections 41A, 41C and 41D can be processing sections while chamber sections 41B and 41D can be non-processing sections.

For example, adjacent processing chamber sections 41C and 41D can use similar process gasses with one of the chambers performing an additional processing action, such as heating, laser annealing, the addition of another process gas without purging the original process gas, etc. In another example, chamber 20 can have adjacent purge chamber sections 41, with one of the purge chamber sections also having laser-annealing capability such as described below.

FIG. 7B is similar to FIG. 7A and illustrates another example of chamber 20 that has six dividers 44, denoted 44A through 44F, that define six chamber regions 41, denoted 41A through 41F. In this six-chamber configuration, every other chamber region can be a non-process section, while the other chamber sections can be process sections that respectively use three different process gases.

In another example, two of the processing sections 41 can respectively use two different process gasses and the third processing section 41 can be used for another process, such as laser annealing, plasma processing, thermal processing, etc. Any reasonable number of chamber sections 41 can be used, e.g., 2 to 12 chamber sections or 3 to 8 chamber sections. A configuration of 4 (four) chamber sections 41 is anticipated to be particular useful because it allows for alternating process sections 41 separated by purge sections or other non-process-gas treatments, such as laser annealing, thermal treatment, etc.

Multichamber ALD System with Laser Annealing

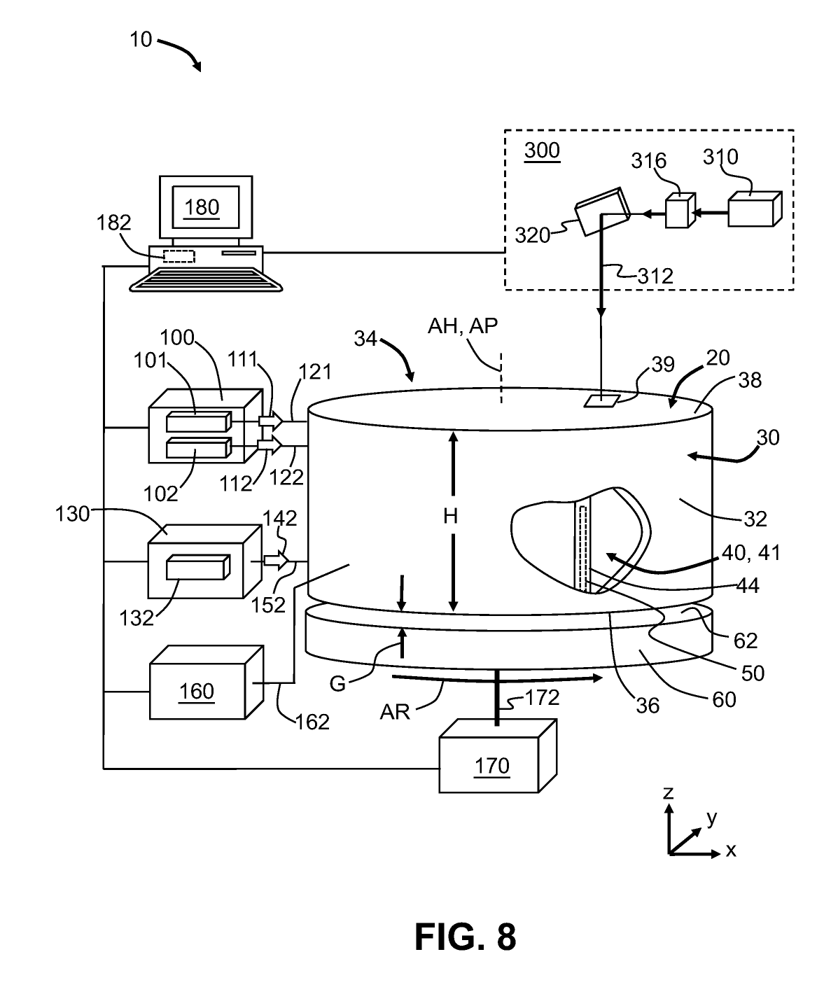

FIG. 8 is similar to FIG. 1 and illustrates an example system 10 that optionally includes a laser system 300 operably arranged relative to chamber 20. The laser system 300 includes a laser 310 that emits a laser beam 312. The laser system 300 can also include a beam-conditioning optical system 316 that conditions and shapes laser beam 312, and a mirror 320 that directs laser beam 312 to a desired location in a given chamber section 41. In an example, laser beam 312 is directed through housing 30 and into a desired chamber section 41 of interior 40 via a window 39 operably arranged in the housing. In another embodiment, the select chamber section 41 can include a interior portion (e.g., in the form of a tube that extends up to laser system 300 and through which laser beam 132 can travel to irradiate wafer surface 72. In an example, laser system 300 is operably connected to controller 180.

Laser beam 312 is made incident upon wafer surface 72 or the ALD film 74 being formed therein. The chamber section 41 to which laser system 300 is operably arranged can be used to perform laser-enhanced ALD (“LE-ALD”). The laser system 300 can be operably arranged with respect to more than one chamber section 41 so that laser processing can be performed more than once for given cycle of wafer 70 through the chamber sections (i.e., multiple laser processing can be performed for each full rotation of platen 60). For example, in the four-chamber-section arrangement discussed above, the two purge chamber sections (say, 40B and 40D) can also be configured as LE-ALD process sections.

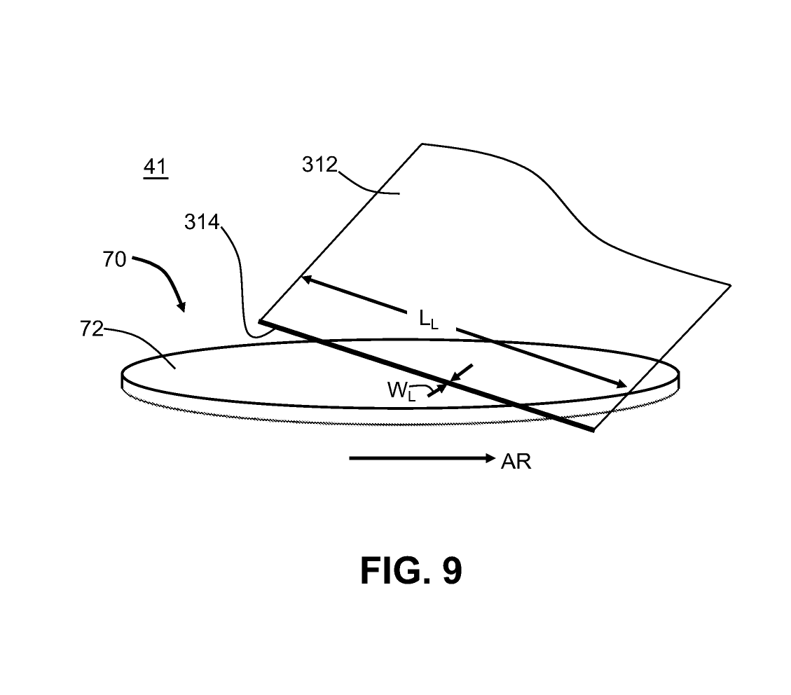

FIG. 9 is a top elevated view of wafer 70 within a chamber section 41 and showing laser beam 312 forming a line image 314 at wafer surface 72. In an example, line image 314 is stationary and the wafer surface (or the ALD film 74 formed thereon) scans under the line image as indicated by arrow AR to perform laser annealing in chamber section 41 to facilitate the ALD film growth process. In an example, chamber section 41 can include the aforementioned purge gas 142 or can include a process gas (e.g., process gas 111 or 112) from process gas system 100, such as one selected to react with the locally heated portion of wafer surface 72 heated by the scanned line image 314 during the annealing or laser-treatment process. The line image 314 is scanned in a direction orthogonal to its long dimension.

In an example, line image 314 has a line length L_{L} that is at least as wide as the width W_{d} of wafer 70 (e.g., a length of L≧200 mm for a 200 mm diameter wafer). The line image 314 also has a line width W_{L}. It is desirable to have the line width W_{L} such that the laser annealing is accomplished in approximately 1 millisecond (ms). If the platen 60 is moving at 60 RPM, and if the platen holds twenty 200-mm wafers, then, the wafers are moving at roughly 4000 mm/sec. A laser beam width of W_{L}=4 mm would produce an annealing time of 1 ms. In an example, the line length L_{L} and the line width W_{L} of line image 134 at wafer surface 72 is defined by beam-conditioning optical system 316. The position of the mirror 320 can be adjusted so that laser beam 312 is incident upon wafer surface 72 at a select angle (e.g., normal incidence, the Brewster angle, etc.).

An example laser annealing process performed using system 10 generates a peak temperature TS at the wafer surface 72 of between 600° C. and 1000° C. If the temperature of platen 60 is at 200° C., then laser beam 312 needs to raise the surface temperature TS of wafer 70 by 400° C. to 800° C.

It is also desirable to use a wavelength λ for laser beam 312 such that the laser beam radiation is absorbed within the thermal diffusion length of the laser anneal. For a 1 ms anneal, and a silicon wafer 70, the thermal diffusion length is roughly 100 microns. Hence, it is desirable that the absorption length be <100 microns. For a silicon wafer, this implies that the laser wavelength λ be less than approximately 1 micron.

It is desirable to have an annealing time of approximately 1 ms at each point on the wafer 70 (i.e., a “dwell time”) because it has been shown that high temperature annealing for short durations produces elastic deformations rather than plastic deformations. This way, the thin ALD film 74 and the silicon wafer expand elastically. This requirement, along with the peak temperature requirement, is sufficient to adequately design laser annealing system 300.

It is noted that in the four-chamber-section embodiment of chamber 20, one or both of chamber sections 41A and 41C can be a laser-annealing process chambers while chamber sections 41B and 41D can be non-processing chambers. Any combination of processing and non-processing chambers consistent with carrying out a viable ALD process can be used in system 10.

Multichamber ALD System with Plasma Processing

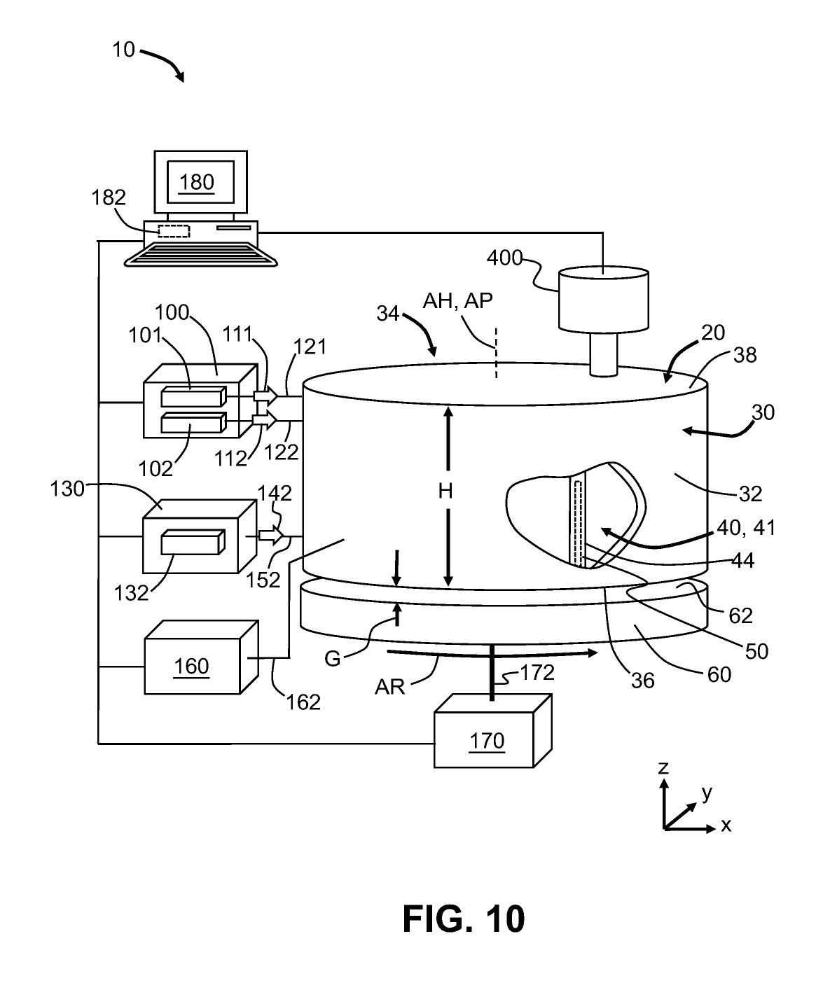

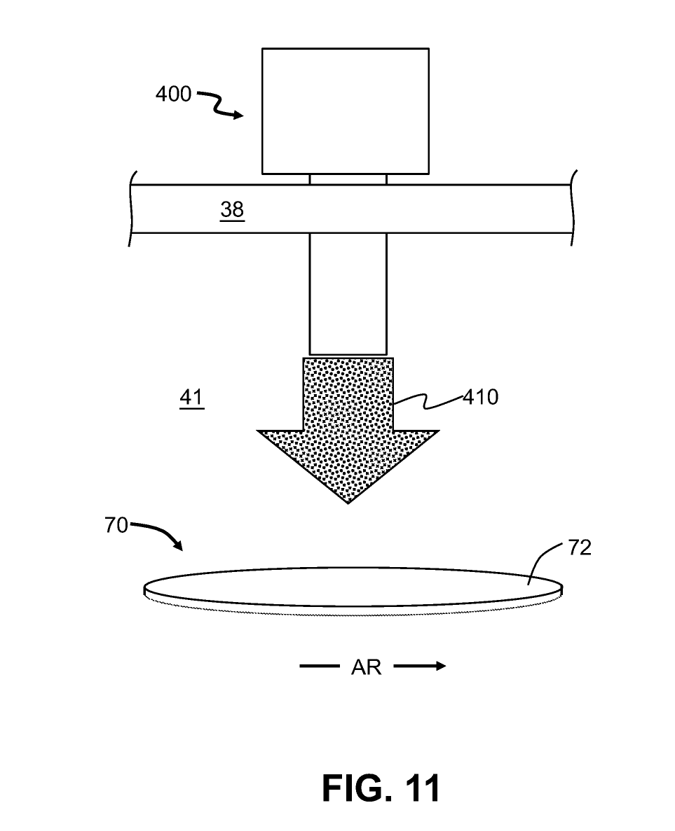

FIG. 10 is similar to FIG. 1 and FIG. 8 and illustrates an embodiment of system 10 that includes a plasma source system 400 operably arranged relative to chamber 20. The plasma source system 400 can be operably connected to controller 180. FIG. 11 is a side elevated view of the plasma source system 400 emitting a plasma 410 that flows toward wafer surface 72 within chamber section 41.

The plasma 410 includes plasma species (e.g., charged ions, such as oxygen radicals O*) that chemically react with wafer surface 72 or film layer 74L that resides on the wafer surface. The plasma 410 moves towards wafer surface 72 due to the pressure differential between the plasma source system 400 and the wafer surface. In an example, plasma source system 400 can be operably arranged relative to more than one chamber section 41. Thus, in an example, system 10 can be used to perform plasma-enhanced ALD (PE-ALD) in at least one of chamber sections 41. In another example, plasma 410 can be used to clean wafers 70 between processing steps, e.g., by providing plasma source system 400 in operable arrangement with respect to a purge or non-process chamber section 41.

Throughput Considerations

The systems and methods disclosed herein are designed to provide relatively high throughput of processed wafers. An example of a high throughput is 10 or more 6-inch wafers per hour having deposited thereon 0.25 micron ore more of material.

Consider now example process of forming GaN using system 10 and the corresponding methods as described above using the basic process set forth in Table 2. A GaN crystal lattice has a dimension of 0.3 nm. At a 60 RPM rotation rate for platen 60, there are 3600 cycles (i.e., full rotations) per hour, with each cycle depositing one ALD film layer 74L, so that we can grow an ALD film 74 with a thickness TH_{F} of about 1 micron of GaN in one hour. The process chamber size (e.g., platen radius R) determines the number of wafers 70 that can fit on the platen 60, but the platen radius R can be made large enough to accommodate more than 20 six-inch wafers on a single platen. This is twice as many wafers and four times the film thickness of the example high-throughput process mentioned above, i.e., represents about an 8× throughput improvement.

It will be apparent to those skilled in the art that various modifications to the preferred embodiments of the disclosure as described herein can be made without departing from the spirit or scope of the disclosure as defined in the appended claims. Thus, the disclosure covers the modifications and variations provided they come within the scope of the appended claims and the equivalents thereto.

What is claimed is:

1. A process chamber for a multichamber atomic layer deposition (ALD) system for performing ALD on multiple wafers, comprising:
a housing having an interior divided into multiple chamber sections by chamber dividers disposed within the housing interior, the housing having an open bottom end;
a rotatable platen having a central axis and an upper surface that supports the multiple wafers and that is operably disposed with its upper surface adjacent the bottom end of the housing and spaced apart therefrom by a gap, wherein the platen is rotatable to move the wafers between the multiple chamber sections; and
a pneumatic valve operably disposed in each chamber divider, wherein each pneumatic valve is in pneumatic communication with the platen surface within the gap and forms a pneumatic partition between adjacent chamber sections.

2. The process chamber according to claim 1, wherein the housing interior has a circular cross-section.

3. The process chamber according to claim 1, wherein the gap is between 50 microns and 500 microns.

4. The process chamber according to claim 1, wherein the platen is configured to rotate at a rotation rate of between 10 and 200 revolutions per minute.

5. The process chamber according to claim 1, wherein the chamber dividers define between three and eight chamber sections.

6. The process chamber according to claim 1, wherein each pneumatic valve includes either:
i) a central purge gas channel sandwiched by two vacuum channels; or
ii) a central vacuum channel sandwiched by two purge gas channels.

7. The process chamber according to claim 1, wherein the multiple chamber sections include:
first and second process chamber sections that are not adjacent and that are operably connected to respective first and second process gas sources; and
first and second non-process chamber sections that are not adjacent and that are operably connected to a purge gas source.

8. The process chamber according to claim 1, further including a laser system operably arranged with respect to at least one of the multiple chamber sections.

9. The process chamber according to claim 1, further including a plasma source system operably arranged with respect to at least one of the multiple chamber sections.

10. The process chamber according to claim 1, wherein each process chamber is configured to accommodate a single wafer.

11. The process chamber according to claim 1, wherein the wafers each have a thickness TH_{W}, and wherein each process chamber section has an interior height H in the range 10·TH_{W}≦H≦50·TH_{W}.

12. The process chamber according to claim 1, wherein the pneumatic valve includes either a V-P-V pneumatic configuration or a P-V-P pneumatic configuration, where V stands for vacuum and P stands for pressure.

13. A multichamber ALD system, comprising:
the process chamber according to claim 1;
a process gas system operably connected to at least two of the chamber sections; and
a purge gas system operably connected to at least two of the chamber sections different than the two chamber sections operably connected to the process gas system.

14. The multichamber ALD system according to claim 13, further comprising at least one of:
i) a laser system operably connected to at least one of the chamber sections; and
ii) a plasma source system operably connected to at least one the chamber sections.

15. The multichamber ALD system according to claim 13, wherein the process gas system contains first and second process gas supplies that respectively contain first and second process gasses.

16. The multichamber ALD system according to claim 13, wherein the multiple chamber sections consist of four chamber sections.

17. The multichamber ALD system according to claim 13, wherein the wafers each have a thickness TH_{W}, and wherein each process chamber section has an interior height H in the range 10·TH_{W}≦H≦50·TH_{W}.

18. The multichamber ALD system according to claim 13, wherein the gap is in the range from 50 microns to 500 microns.

19. The multichamber ALD system according to claim 13, wherein each process chamber is configured to accommodate a single wafer.

20. A method of performing atomic layer deposition (ALD) on multiple wafers each having a surface to form an ALD film on each of the wafers, comprising:
supporting the multiple wafers on a surface of a platen that is spaced apart from a process chamber housing by a gap G that is 500 microns or less, wherein the process chamber includes multiple chamber sections;
pneumatically partitioning the process chamber sections;
rotating the platen beneath the process chamber housing, thereby causing the wafers to move between the chamber sections; and
performing an ALD process in at least one of the chambers sections as the wafers pass through the chamber sections to form the ALD film.

21. The method according to claim 20, wherein rotating the platen includes continuously rotating the platen.

22. The method according to claim 20, wherein the pneumatic partitioning is performed by pneumatic valves in pneumatic communication with the platen surface through the gap.

23. The method according to claim 22, wherein the pneumatic valve includes either a V-P-V pneumatic configuration or a P-V-P pneumatic configuration, where V stands for vacuum and P stands for pressure.

24. The method according to claim 20, further comprising performing a first ALD process in a first chamber section and performing a second ALD process in a second chamber section that is not adjacent the first chamber section.

25. The method according to claim 20, wherein each full rotation of the platen forms an ALD film layer on each wafer, and including performing multiple full rotations of the platen to form an ALD film made up of multiple ALD film layers.

26. The method according to claim 25, further comprising passing the wafers through at least one chamber section that includes a gas that does not chemically react with the surfaces of the wafers or the ALD film layer.

27. The method according to claim 20, further comprising performing a laser process in at least one of the chamber sections.

28. The method according to claim 27, wherein the laser process includes forming a stationary line image and moving the wafer relative to the line image.

29. The method according to claim 27, wherein the laser process is performed in the presence of a process gas to perform a laser-enhanced ALD process.

30. The method according to claim 20, further comprising performing a plasma process in at least one of the chamber sections.

31. The method according to claim 20, including performing multiple rotations of the platen so that the wafers pass through each of the chamber sections multiple times, thereby forming an ALD film on each of the surfaces of the wafers.

32. The method according to claim 20, wherein the rotating of the platen is performed at a rotation rate of between 10 rotations per minute (RPM) and 200 RPM.

33. The method according to claim 32, wherein the rotation rate is between 30 and 100 RPM.

33. The method according to claim 30, wherein the rotating of the platen is performed at a rotation rate that provides each wafer with a residence time within the chamber sections of between 250 milliseconds and 500 milliseconds.
